(19) United States
(12) Patent Application Publication
(10) Pub. No.: US 2021/0147977 A1
(43) Pub. Date: May 20, 2021

(54) DENSIFIED SOLID PREFORMS FOR SUBLIMATION

(71) Applicant: ENTEGRIS, INC., Billerica, MA (US)

(72) Inventors: Bryan C. HENDRIX, Danbury, CT (US); Robert L. WRIGHT, JR., Newtown, CT (US)

(21) Appl. No.: 17/097,855

(22) Filed: Nov. 13, 2020

Related U.S. Application Data
(60) Provisional application No. 62/935,235, filed on Nov. 14, 2019.

(51) Int. Cl. C23C 16/448; C23C 16/458; C23C 16/02; C23C 16/08

(52) U.S. Cl. CPC C23C 16/448; C23C 16/08; C23C 16/0281; C23C 16/4581

(57) ABSTRACT

Solid preforms include a solid sublimation material surrounding a support phase. The preforms combine a solid to be sublimated for use in vapor deposition with a compatible support phase allowing the preform to maintain a shape as the solid sublimates. The preforms may be included in ampules for use in vapor deposition systems. The ampules may include one or more of the preforms, and the preforms may be oriented with respect to one another to control flow within the ampule. The preforms may be made via pressing a powder of the solid sublimation material onto the support phase, or by removing a solvent from a solution of the solid sublimation material.

### FIELD

This disclosure relates to solid sublimation materials for producing a vapor for depositing a film onto a substrate, and more particularly to preforms including the solid sublimation material surrounding a support phase.

### BACKGROUND

Vapor deposition may include deposition using solid materials that are vaporized through sublimation. These solid materials are typically included in an ampule, which is heated to cause sublimation. The solid materials typically are added to the ampule in the form of a powder. The powder may be used to fill the ampule or may be distributed among trays or compartments contained within the ampule. Vapor supplied from the ampules may be used in, for example, semiconductor manufacturing processes.

### SUMMARY

This disclosure relates to solid sublimation materials for producing a vapor for depositing a film onto a substrate, and more particularly to preforms including the solid sublimation material surrounding a support phase.

Typically, ampules are filled with powders of the solid sublimation material. This can be a slow, manual process that requires precise filling, often under glove-box conditions to avoid moisture or contaminants from being included in the ampule. By using preforms including the solid sublimation material, the ampule filling process can be streamlined due to simplified handling of the preforms.

Further, powders can have low density, resulting in rapid consumption of the contents of an ampule. By providing a more dense form of the solid sublimation material, for example by pressing or depositing the solid sublimation material, density of the solid sublimation material that is included in an ampule can be improved, reducing the frequency of changing and refilling ampules of the solid sublimation material.

Additionally, as the powder sublimates, the surface presented by the solid sublimation material changes and thus the sublimation properties and the circulation of vapor within the ampule may also vary over time. Using a preform with defined channels and a distributed support phase allows more consistent sublimation and vapor flow than powders or solid blocks of a solid sublimation material alone.

Solid sublimation material can be provided as a preform having a defined shape. Preforms according to embodiments of this disclosure include the solid sublimation material surrounding a support phase. The solid sublimation material is the material that is sublimated to provide a vapor, for example for use in a vapor deposition tool. The support phase allows the preform to hold a shape allowing the solid sublimation material to be consistently sublimated to provide vapor for use in a deposition tool. The preforms may include channels and grooves to provide this consistent sublimation. The preform may be created by, for example, pressing a powder of the solid sublimation material around the support phase, or providing a solution of the solid sublimation material and removing the solvent. One or more of the preforms may be included in a solids delivery ampule provided for use with a vapor deposition system.

In an embodiment, a preform for sublimation includes a support phase and a solid sublimation material. The solid sublimation material surrounds at least a portion of the support phase. The preform includes a plurality of channels through the preform.

In an embodiment, the solid sublimation material is pressed powder.

In an embodiment, the support phase includes a metal foam, a lattice of solid metal, one or more metal wires, or a metal wool.

In an embodiment, the support phase includes carbon fibers or ceramic fibers.

In an embodiment, the preform further includes a foil at one of a top surface of the preform or a bottom surface of the preform.

In an embodiment, the preform further includes a foil at a side surface of the preform.

In an embodiment, the solid sublimation material is aluminum chloride. In an embodiment, the support phase includes aluminum.

In an embodiment, the solid sublimation material includes Mo or W. In an embodiment, the support phase includes nickel.

In an embodiment, the preform includes a plurality of grooves on a surface of the preform.

In an embodiment, an ampule for delivery of a vapor includes an ampule body having a vapor outlet port. The ampule body defines an internal space containing one or more sublimation preforms. Each sublimation preform includes a support phase and a solid sublimation material. The solid sublimation material surrounds at least a portion of the support phase. The preform includes a plurality of channels through the preform.

In an embodiment, the ampule body further includes a carrier gas inlet.

In an embodiment, the ampule includes more than one sublimation preforms, and each of the sublimation preforms includes the same solid sublimation material.

In an embodiment, the ampule body contains a plurality of the sublimation preforms, and the sublimation preforms are arranged such that the channels of each sublimation preform do not align with channels of adjacent sublimation preforms.

In an embodiment, a method for preparing a solid sublimation material includes obtaining a support phase, surrounding at least a portion of the support phase with a solid sublimation material, and preparing a preform including the support phase and the solid sublimation material, where the solid sublimation material surrounds at least a portion of the support phase.

In an embodiment, the solid sublimation material is provided in a form of a powder, and preparing the preform comprises pressing the powder and the support phase. In an embodiment, the pressing the powder and the support phase includes heating the powder.

In an embodiment, the solid sublimation material is provided in a form of a solution including the solid sublimation material and a solvent, and preparing the preform comprises removing the solvent from the solution.

In an embodiment, the solid sublimation material is provided as a vapor, and preparing the preform comprises condensing the vapor of the solid sublimation material over the support phase.

In an embodiment, the solid sublimation material is provided in a molten form, and preparing the preform comprises cooling the molten solid sublimation material.

In an embodiment, the method further includes placing the preform into a solids delivery ampule.

In an embodiment, preparing the preform is performed in a mold configured to form a plurality of channels through the preform and to form a plurality of grooves along at least one surface of the preform.

In an embodiment, the method further includes drilling one or more channels in the preform and/or cutting a plurality of grooves along at least one surface of the preform.

In an embodiment, preparing the preform includes contacting at least one of the solid sublimation material and the support phase with a foil.

### DRAWINGS

The disclosure may be more completely understood in consideration of the following description of various illustrative embodiments in connection with the accompanying drawings.

FIG. 1A shows a perspective view of a preform according to an embodiment.

FIG. 1B shows a cross-sectional view of the preform shown in FIG. 1A according to an embodiment.

FIG. 1C shows a top view of the preform shown in FIG. 1A according to an embodiment.

FIG. 1D shows a cross-sectional view of the preform shown in FIG. 1A, with a foil, which is a thin layer of an involatile solid, applied to the preform according to an embodiment.

FIG. 2 shows a schematic cross-sectional view of an ampule according to an embodiment.

FIG. 3 shows a schematic cross-sectional view of an ampule according to an embodiment.

FIG. 4 shows a flowchart of a method for preparing a preform.

FIG. 5A-5C shows an example the different vaporized phases from the prepared and initial form of the preform (FIG. 5A & FIG. 5B) through the subsequent stages of vaporization of the preform.

### DETAILED DESCRIPTION

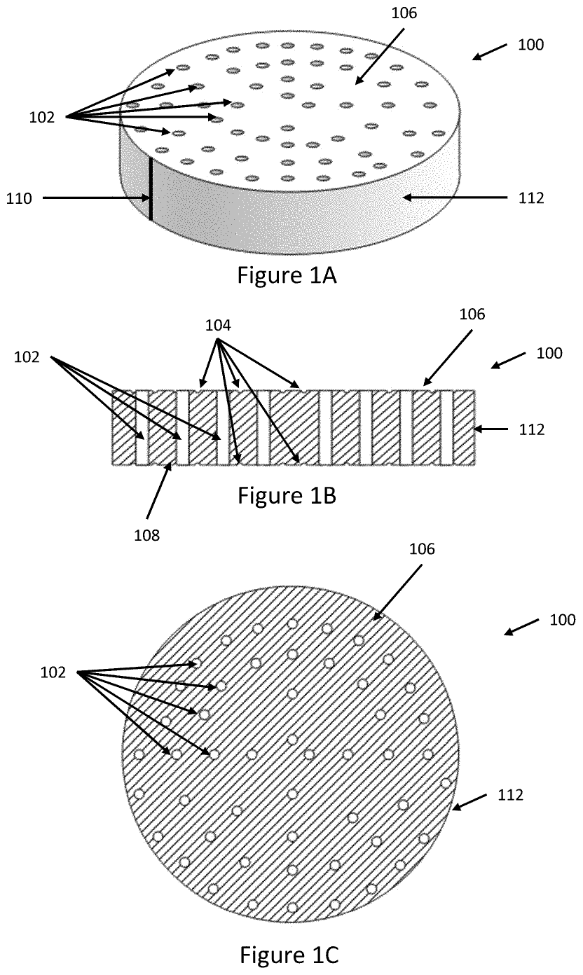

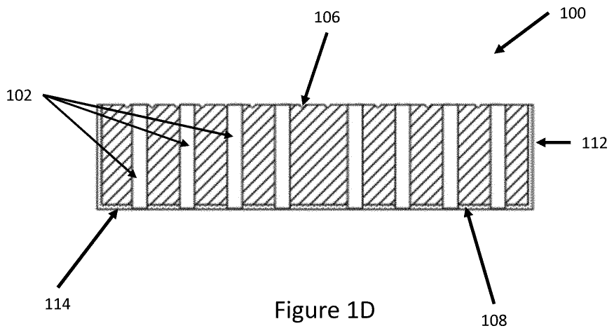

FIGS. 1A-1C show various views of a preform 100 according to an embodiment of the disclosure. FIG. 1D shows the preform shown in FIG. 1A, with a foil applied to the preform according to an embodiment of the disclosure.

Preform 100 may include a solid sublimation material surrounding a support phase. In an embodiment, the solid sublimation material surrounds the support phase. The solid sublimation material is a material sublimated to provide a vapor in a vapor deposition tool. The solid sublimation material may be any suitable solid that is sublimated to provide vapor that is deposited by the vapor deposition tool. The support phase is a different material from the solid sublimation material. The support phase may be selected for compatibility with the solid sublimation material. The support phase may not evaporate substantially under the operating conditions of a solids delivery ampule and/or vapor deposition tool including the preform 100. The support phase may be selected such that it does not contaminate a vapor of the solid sublimation material. In an embodiment, the support phase is incorporated into the solid sublimation material. In an embodiment, the solid sublimation material completely surrounds the support phase. In an embodiment, some of the support phase is exposed. In an embodiment, the solid sublimation material is a pressed powder. In an embodiment, the solid sublimation material is a precipitate formed on the support phase. In an embodiment, the solid sublimation material is a solid condensed on the support phase from a vapor. In an embodiment, the solid sublimation material is solidified around the support phase from a molten material. The solid sublimation material can have a density that is greater than the density of a powder of that same solid sublimation material. In an embodiment, a preform 100 includes a greater mass of the solid sublimation material than an equivalent volume of the solid sublimation material when it is provided in a powdered form.

The solid sublimation material is a solid material to be provided to a vapor deposition system as a vapor. The solid sublimation material may be any suitable solid material that is used in vapor deposition processes. The solid sublimation material may include, as non-limiting examples, AlCl₃, tungsten halides and oxyhalides including but not limited to WCl₅, WCl₆ and WOCl₄, and molybdenum halides and oxyhalides including but not limited to MoCl₅, MoOCl₄, and MoO₂Cl₂. In an embodiment, the solid sublimation material is MoOₓCl_{y} or WOₓCl_{y} where x=0, 1, or 2 and y=6-2x or y=5-2x. In an embodiment, the solid sublimation material comprises ZrCl₄ or HfCl₄. Other non-limiting examples of solid sublimation materials include SiI₄, In(CH₃)₃, Ti(OCH₃)₄, TaF₅, NbF₅, TaCl₅, NbCl₅, W(CO)₆, Mo(CO)₆, and the like.

The support phase provides structure to the preform allowing the preform to maintain its shape as solid sublimation material is consumed. The support phase maintains a shape of the solid sublimation material prior to and during sublimation of the solid sublimation material. The shape may include a general shape of the preform 100, for example a cylindrical or disc shape, a rectangular prism shape, a hexagonal prism shape, a dodecahedron, or any other such suitable shape for the preform 100. The shape may be based on the design of an ampule that the preform 100 is used with, such as the shape of the interior space of the ampule or the flow geometry during use of an ampule containing the preform 100.

In an embodiment, the support phase includes pyrolytic carbon. In an embodiment, the pyrolytic carbon is provided as a plurality of carbon fibers. In an embodiment, the fibers may be pressed into a form, such as a pellet. In an embodiment, the support phase is a metallic structure. In an embodiment, the support phase includes an alloy. In an embodiment, the support phase is a metallic foam. In an embodiment, the support phase includes one or more metal wires. In an embodiment, the support phase includes a metal wool. In an embodiment, the support phase is a material selected based on high thermal conductivity.

In an embodiment, the support phase is a material selected for compatibility with the solid sublimation material. Compatibility may be in terms of cohesion between the solid sublimation material and the support phase. Compatibility may further be restricted by materials which would not contaminate the vapor provided by the solid sublimation material.

Non-limiting examples of compatible materials for a support phase when AlCl₃ is the solid sublimation material include aluminum metal and ceramics including Al₂O₃. The ceramics including Al₂O₃ may, for example, include the Al₂O₃ in the ceramic or the Al₂O₃ may be a coating on the support phase.

Non-limiting examples of compatible materials for a support phase when the solid sublimation material includes tungsten halides and oxyhalides include pyrolytic carbon, nickel metal, nickel based alloys such as C22 or C247 nickel alloys, ceramics, or glasses, or combinations thereof.

Non-limiting examples of compatible materials for a support phase when the solid sublimation material includes molybdenum halides and oxyhalides include pyrolytic carbon, nickel metal, nickel based alloys such as C22 or C247 nickel alloys, ceramics, or glasses, or combinations thereof.

The preform 100 provides the solid sublimation material such that it can be sublimated, for example at and above particular ambient temperatures, such as during heating of a solids delivery ampule containing the preform 100. The support phase allows the preform 100 to maintain shape as solid sublimation materials are sublimated, and provides structural support for elements of the preform including, for example, channels 102 and grooves 104. The support phase may further facilitate heat transfer through the preform 100, for example due to thermal conductivity of the support phase materials.

As shown in FIG. 1A, preform 100 includes channels 102 extending through preform 100. In an embodiment, grooves 104, as shown in FIG. 1B, can be formed in top surface 106 and bottom surface 108 of the preform 100. In some embodiments, an alignment line 110 can also be included in the preform 100, for example, on circumferential surface 112.

Additionally, in some embodiments, the preform 100 can include one or more apertures (not shown) to accommodate parts of a solids delivery ampule that preform 100 is used with, such as a tube conveying a carrier gas within the ampule.

Channels 102 are holes or pores formed through the preform 100, from the top surface 106 to the bottom surface 108. The channels 102 allow vapor to pass through or escape the preform 100. This may provide more even sublimation of the solid sublimation material. In an embodiment, the channels 102 may be cylindrical in shape. In an embodiment, the channels 102 may be tapered such that they have a truncated cone shape. The truncated cone shape may facilitate removal of the preform 100 from a mold in which the preform 100 is formed. The diameter of the channels 102 may be selected to be greater than a mean free path of the vapor sublimated from the solid sublimation material. In other words, a diameter of the channel is greater than the average distance of a molecule of the vapor that travels prior to colliding with another molecule of the vapor. In an embodiment, the channels 102 have a diameter of from 10 μm to 10 mm. In an embodiment, the diameter of the channels 102 can be selected based at least in part on a pressure gradient within the preform 100 or between multiple preforms. In an embodiment, the channels 102 have a diameter of between 10 μm and 100 μm. In an embodiment, the channels 102 have a diameter of between 1 and 10 mm.

Grooves 104, as shown in FIG. 1B, can be formed in top surface 106 and/or bottom surface 108 of the preform 100. In an embodiment, grooves 104 are straight. In an embodiment, grooves 104 may be curved, for example forming a wave pattern or a spiral pattern. Grooves 104 may provide a path for vapor to pass between channels 102 of a preform 100 and channels of an adjacent preform. Grooves 104 may provide a tortuous path to increase the distance traveled by vapor along the preform 100 and/or adjacent preforms prior to reaching a vapor outlet of an ampule. Alternatively or in addition to grooves 104, the top surface 106 and/or bottom surface 108 may be roughened.

One or more alignment lines 110 may also be included in the preform 100 on a circumferential surface 112, as shown in FIG. 1A. The alignment line or lines 110 indicate the orientation of the preform. In an embodiment, the alignment line 110 can be a linear projection, projecting outwards and away from the circumferential surface 112. In another embodiment, the alignment line can be a groove formed in the circumferential surface 112. The alignment line 110 may be used when stacking multiple preforms 100 to align the preforms with respect to one another. The alignment of the preforms assisted by reference to alignment lines 110 can be such that the channels 102 of adjacent preforms are not aligned with one another. By not aligning the channels 102 of adjacent preforms 100, vapor can be forced to travel from one set of channels 102 to the next via, for example, grooves 104. Using alignment lines 110 of adjacent preforms to orient the preforms with respect to one another in this manner thus provides a tortuous path for the vapor, improving the consistency of saturation of the vapor ultimately produced within an ampule including one or more of the preform 100.

FIG. 1B shows a cross-sectional view of the preform 100 depicted in FIG. 1A. As shown in the sectional view of FIG. 1B, the channels 102 extend through the preform 100. Grooves 104 are visible on top surface 106 and bottom surface 110 of the preform 100. In the embodiment shown in FIG. 1B, the grooves 104 are straight and extend in a direction into the page in the sectional view shown in FIG. 1B.

FIG. 1C shows a top view of the preform according to an embodiment. Channels 102 are visible on the top surface 106 in the view of FIG. 1C. The distribution of channels 102 shown in FIG. 1C is such that if two adjacent preforms are rotated 180° with respect to one another, the channels 102 of the two adjacent preforms are not aligned with one another. As shown in FIG. 1C that the channels 102 extend through the entirety of preform 100, from top surface 106 to bottom surface 108 of the preform 100.

FIG. 1D shows a cross-sectional view of the preform shown in FIG. 1A, with a metal foil 114 applied to the preform according to an embodiment. The metal foil 114 can be a thin layer of an involatile solid. The metal foil 114 can be applied to one or more faces of the preform 100, such as the top surface 106 or the bottom surface 108. In an embodiment, the metal foil may further surround the sides of the preform 100, such as circumferential surface 112. The metal foil 114 may include through holes. The through holes may or may not correspond to all of the channels 102 formed in the preform 100. The metal foil 114 may further contribute to the tortuous path for the vapor to pass by or through one or more preforms 100 in a solids delivery ampule. In an embodiment, the metal foil 114 can be included in preform 100 as part of the support phase of the preform. When included in the support phase, the metal foil 114 can further facilitate the conduction of heat through the preform 100.

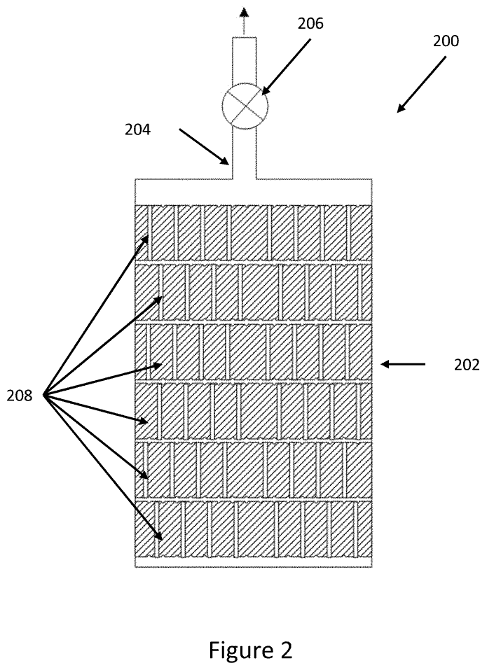

FIG. 2 shows a cross-sectional view of an ampule 200 according to an embodiment. Ampule 200 is an ampule for delivery of a vapor sublimated from a solid sublimation material. Ampule 200 is sized to be compatible with a vapor deposition system. The vapor deposition system includes a heated chamber in which ampule 200 can be heated, in turn heating and sublimating solid sublimation materials contained within the ampule 200.

Ampule 200 includes an ampule body 202 and vapor outlet 204. Vapor outlet valve 206 regulates flow from vapor outlet 204. Ampule body 202 defines an internal space. A plurality of preforms 208 is located within the internal space. The plurality of preforms 208 includes two or more preforms such as preform 100 described above with reference to FIGS. 1A-1C. The preforms of the plurality of preforms 208 may be stacked on top of one another. In an embodiment, the preforms of the plurality of preforms 208 contact one another when stacked. In an embodiment, a spacer is provided between each pair of adjacent preforms in the plurality of preforms 208. In an embodiment, each of the preforms in the plurality of preforms are supported, for example by structures such as projections from an inner surface of the ampule body 202. In an embodiment, a heater jacket (not shown) may be provided surrounding ampule 200. In an embodiment, heating rods or heating fins (not shown) may extend into the internal space within ampule body 202.

Ampule body 202 may be the portion in contact with the heated chamber of the vapor deposition system and transfer heat to the internal space to heat the internal space and produce vapor of the solid sublimation material. Ampule body 202 may be, for example, cylindrical in shape. Ampule body 202 may be sealed such that the only passage into and out of the internal space within ampule body 202 is by vapor outlet 204. Ampule body 202 may be sealed following placement of the plurality of preforms 208 within the ampule body 202.

Vapor outlet 204 is an opening in ampule body 202 that allows vapor including the sublimated solid sublimation material or materials from the plurality of preforms 208 to be provided to a vapor deposition tool. Vapor outlet valve 206 regulates the passage of vapor from vapor outlet 204, and can be any suitable valve for regulating or controlling flow of a vapor. Vapor outlet valve 206 may be controlled by a controller (not shown) of the ampule 200 and/or a controller (not shown) of the vapor deposition tool that ampule 200 is used with.

A plurality of preforms 208 is located within the internal space defined by ampule body 202. The preforms of the plurality of preforms 208 may be preforms such as preform 100 described above and shown in FIGS. 1A-1C. The preforms each include a solid sublimation material surrounding a support phase. The solid sublimation material may be, for example, AlCl₃, a tungsten chloride or oxychloride, or a molybdenum chloride or oxychloride. The support phase may be carbon fibers, pyrolytic carbon, metallic, for example a metal foam, a ceramic, or a glass. In an embodiment, the support phase is a material selected based on high thermal conductivity. The support phase may be selected based on compatibility with the solid sublimation material, for example as described above. The number of preforms in the plurality of preforms 208 can be selected based on the ampule, for example including from two to ten preforms for an ampule supplying a single vapor deposition tool to as many as hundreds of preforms in an ampule feeding vapor to multiple vapor deposition tools. In some embodiments, the plurality of preforms 208 may each include the same solid sublimation material. In some embodiments, the plurality of preforms 208 may include different solid sublimation materials in at least some of the preforms 208. Each of the plurality of preforms 208 includes channels passing through the preform from a first surface to a second surface opposite the first. Each of the plurality of preforms 208 may include grooves formed on one or more faces of the preforms. In an embodiment, the grooves may be on opposing sides of each of the preforms. In an embodiment, the grooves of at least one of two adjacent preforms may convey vapor from the channels of one preform to the channels of the adjacent preform.

The plurality of preforms may be arranged such that the channels such as channels 102 of adjacent preforms in the plurality of preforms 208 do not align with one another. The arrangement of the plurality of preforms may be ensured by referencing an alignment line such as alignment line 110, for example ensuring that the alignment lines of adjacent preforms 208 do not align with one another. The alignment of the plurality of preforms 208 to ensure that channels of adjacent preforms are misaligned with respect to one another can provide a tortuous path for carrier gas or vapor through the ampule. The vapor may travel along grooves formed in the surfaces of preforms, such as grooves 104 described above, to pass from the channels of one preform to the channels of the adjacent preform. The tortuous path may improve saturation of the vapor with the sublimated solid sublimation material. In an embodiment, a metal foil may be included on, under, or within the preform. In an embodiment, a metal foil is used on one or more faces of the preform. The metal foil may include through holes. The through holes may not correspond to all of the channels formed in the preform. The metal foil may further contribute to the tortuous path for the vapor. The metal foil may be part of the support phase of the preform. The metal foil may conduct heat through the preform.

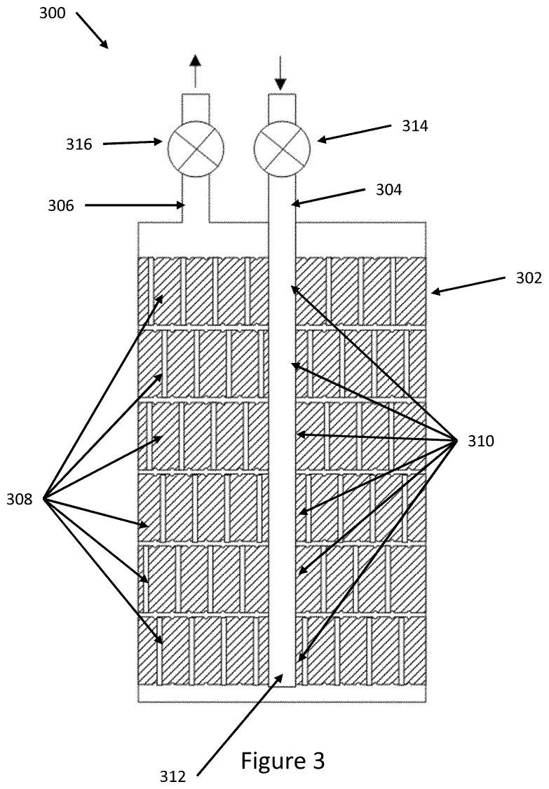

FIG. 3 shows a cross-sectional view of an ampule 300 according to another embodiment. Ampule 300 includes an ampule body 302. In the embodiment shown in FIG. 3, the ampule body 302 includes a carrier gas inlet 304 and a vapor outlet 306. Ampule body 302 defines an internal space. A plurality of preforms 308 each including solid sublimation material and a support phase is located within the internal space. The preforms 308 may each include an aperture 310 configured to allow a carrier gas tube 312 to extend through the plurality of preforms 308. In the embodiment shown in FIG. 3, carrier gas tube 312 is straight. In embodiments, the carrier gas tube may include curves. The carrier gas tube 312 extends from carrier gas inlet 304 to a point in the internal space within ampule 300 where the carrier gas is to be conveyed.

Ampule 300 is an ampule for delivery of a vapor sublimated from a solid. Ampule 300 is sized to be compatible with a vapor deposition system. The vapor deposition system includes a heated chamber in which ampule 300 can be heated, in turn heating and sublimating contained solid sublimation materials.

Ampule 300 includes ampule body 302. Ampule body 302 defines an internal space within which the plurality of preforms is contained. Ampule body 302 may be the portion in contact with the heated chamber of the vapor deposition system and transfer heat to the internal space to heat the internal space and produce vapor of the solid sublimation material. Ampule body 302 may be, for example, cylindrical in shape. Ampule body 302 may be sealed such that the only passage into and out of the internal space within ampule body 302 is by carrier gas inlet 304 and vapor outlet 306. Ampule body 302 may be sealed following placement of the plurality of preforms 308 within the ampule body 302.

In the embodiment shown in FIG. 3, ampule 300 includes a carrier gas inlet 304. Carrier gas inlet 304 includes a valve 314 regulating a flow of carrier gas into the internal space defined by the ampule body 302. The carrier gas may be any suitable gas composition that preserves the integrity of precursor vapor provided by the solid sublimation. The carrier gas may be, for example, an inert gas. Non-limiting examples of carrier gases may include argon, helium, nitrogen, carbon monoxide, and the like. The carrier gas may be a mixture of gases. Carrier gas inlet 304 is configured to be connected to a carrier gas source (not shown), such as, for example, a line from the vapor deposition tool or a line from a tank or other source supplying the carrier gas. Carrier gas inlet 304 may be attached to or may extend to be carrier gas tube 312 within the internal space defined by the ampule body 302. Carrier gas may be introduced to drive flow of vapor through vapor outlet 306 and/or to promote the sublimation of the solid sublimation material to form the vapor.

Carrier gas tube 312 conveys the carrier gas within the ampule body to where it is released. In the embodiment shown in FIG. 3, carrier gas tube 312 conveys the carrier gas past all of the plurality of preforms 308 to an end of the internal space defined by ampule body 302 that is opposite the end including vapor outlet 306. The carrier gas tube 312 extends through the plurality of preforms 308 through apertures included in each of the plurality of preforms 308.

Vapor outlet 306 is an opening by which vapor including the sublimated solid sublimation material and optionally carrier gas supplied via the carrier gas inlet 304 may leave ampule 300 and, for example, pass into a heated tube conveying the vapor to a deposition chamber of the vapor deposition tool. Vapor outlet 306 may include a valve 316 to regulate flow of vapor out of the ampule 300 through the vapor outlet 306. Vapor outlet 306 may be located at a top of the internal space defined by ampule body 302 such that vapor of the solid sublimation material rises towards the vapor outlet.

The ampule 300 contains a plurality of preforms 308. The plurality of preforms 308 may each include an aperture 310. Each of the plurality of preforms 308 may be a preform such as preform 100 shown in FIGS. 1A-1C and described above. The aperture 310 may allow the carrier gas tube 312 to pass through each of the plurality of preforms 308. Each of the plurality of preforms 308 includes a solid sublimation material and a support phase. The solid sublimation material may be, for example, AlCl₃, a tungsten chloride or oxychloride, or a molybdenum chloride or oxychloride or combinations thereof. The support phase may be carbon fibers, pyrolytic carbon, metallic, for example a metal foam, a ceramic, or a glass. The support phase may be selected based on compatibility with the solid sublimation material, for example as described above. Each of the plurality of preforms 308 includes channels passing through the preform from a first surface to a second surface opposite the first. The plurality of preforms 308 may each include the same solid sublimation material. In an embodiment, the plurality of preforms 308 may include different solid sublimation materials in at least some of the preforms 308. Each of the plurality of preforms 308 may include grooves formed on one or more of the top and bottom sides of the preforms. In an embodiment, the grooves may be on opposing sides of each of the preforms. In an embodiment, the grooves of at least one of two adjacent preforms may convey vapor from the channels of one preform to the channels of the adjacent preform.

The plurality of preforms may be arranged such that the channels such as channels 102 of adjacent preforms in the plurality of preforms 308 do not align with one another. The arrangement of the plurality of preforms may be ensured by referencing an alignment line such as alignment line 110, for example ensuring that the alignment lines of adjacent preforms 308 do not align with one another. The alignment of the plurality of preforms 308 may be to provide a tortuous path for carrier gas or vapor through the ampule. The vapor may travel along grooves formed in the surfaces of preforms, such as grooves 104 described above, to pass from the channels of one preform to the channels of the adjacent preform. The tortuous path may improve saturation of the vapor with the sublimated solid sublimation material. In an embodiment, a metal foil may be included on, under, or within the preform. In an embodiment, a metal foil is used on one or more faces of the preform. The metal foil may include through holes. The through holes may not correspond to all of the channels formed in the preform. The metal foil may further contribute to the tortuous path for the vapor. The metal foil may be part of the support phase of the preform. The metal foil may conduct heat through the preform.

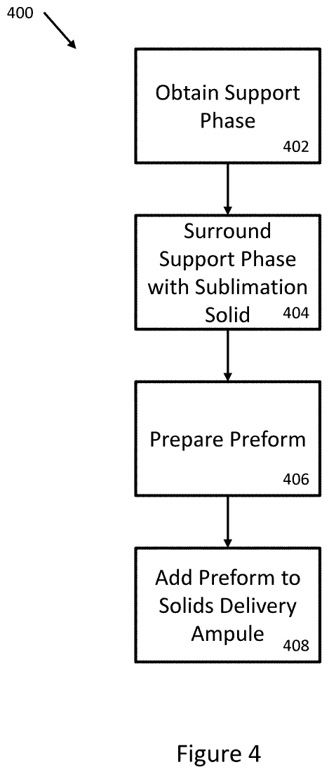

FIG. 4 shows a flowchart of a method 400 for preparing a preform. The method 400 includes obtaining a support phase 402, surrounding at least a portion of the support phase with a solid sublimation material 404, and preparing a preform 406 including the support phase and the solid sublimation material, wherein the solid sublimation material surrounds at least a portion of the support phase. The preform may optionally be added to a solids delivery ampule 408.

A support phase 402 is obtained. In an embodiment, the support phase is a plurality of carbon fibers. In an embodiment, the support phase is pyrolytic carbon. In an embodiment, the support phase is a metallic or ceramic structure. In an embodiment, the support phase is a metal foam, for example, a nickel foam or an aluminum foam. In an embodiment, the support phase is a material selected based on compatibility with the solid sublimation material. Compatibility may be in terms of cohesion between the solid sublimation material and the support phase. Compatibility may further be restricted by materials which would not contaminate the vapor provided by the solid sublimation material. Non-limiting examples of compatible materials for the support phase when AlCl₃ is the solid sublimation material include aluminum metal, ceramics including Al₂O₃. The ceramics including Al₂O₃ may, for example, include the Al₂O₃ in the ceramic or the Al₂O₃ may be a coating on the support phase. Non-limiting examples of compatible materials for the support phase when the solid sublimation material includes tungsten halides and oxyhalides include pyrolytic carbon, nickel metal, nickel based alloys such as C22 or C247 nickel alloys, ceramics, or glasses, or combinations thereof. Non-limiting examples of compatible materials for the support phase when the solid sublimation material includes molybdenum halides and oxyhalides include pyrolytic carbon, nickel metal, nickel based alloys such as C22 or C247 nickel alloys, ceramics, or glasses, or combinations thereof. In an embodiment, the support phase is a material selected based on high thermal conductivity.

The support phase is surrounded with a solid sublimation material 404. The solid sublimation material may be selected from, for example, AlCl₃, tungsten halides or oxyhalides, or molybdenum halides or oxyhalides. In an embodiment, when the support phase is a plurality of carbon fibers, surrounding the support phase with the solid sublimation material at 404 may include mixing the carbon fibers with a powder of the solid sublimation material. In an embodiment, a mold is obtained and the mixture of carbon fibers and powder may occur within a mold. In an embodiment, the mixed fibers and powder may be placed into the mold. In an embodiment where the support phase is a ceramic or metal piece, surrounding the support phase with a solid sublimation material at 404 may include surrounding the support phase with a powder of the solid sublimation material within part of a mold. In an embodiment where the support phase is a ceramic or metal piece, surrounding the support phase with a solid sublimation material at 404 may include surrounding the support phase with a solution including the solid sublimation material within a mold. As a non-limiting example, the solution including the solid sublimation material may include Ti(OCH₃)₄ as the solid sublimation material and the solvent may include, as a non-limiting example, hexanes. In an embodiment, surrounding the support phase with a solid sublimation material at 404 may include pouring a melted solid sublimation material, including as a non-limiting example, MoO₂Cl₂ at a temperature above 176° C. over the support phase. In an embodiment, surrounding the support phase with a solid sublimation material at 404 may include supplying a vapor including the solid sublimation material around the support phase.

A preform including the support phase and the solid sublimation material, wherein the solid sublimation material surrounds at least a portion of the support phase is prepared at 406. In an embodiment where the solid sublimation material is provided as a powder at 404, the preform may be prepared at 406 by closing the mold and applying pressure to form a pressed powder of the solid sublimation material on the support phase. Pressing a powder solid sublimation material may be performed at an elevated temperature by heating the mold and/or the powder during pressing. In an embodiment, a temperature at which 80% or more than 80% or 90% or more than 90% of the powder solid sublimation material softens is used for pressing the powder solid sublimation material. In an embodiment, a temperature at which the powder solid sublimation material can be densified more quickly at lower pressures than the pressure at the ambient temperature is used for pressing the powder solid sublimation material. In an embodiment where the solid sublimation material is provided as a solution in 404, the preform may be prepared at 406 by evaporating the solvent from the solution while the solution and the support phase are within a mold. In an embodiment where the solid is provided in molten form at 404, the preform may be prepared at 406 by cooling the molten solid sublimation material within a mold. In an embodiment where the solid is provided as a vapor at 404, the preform may be prepared at 406 by condensing the vapor onto the support phase.

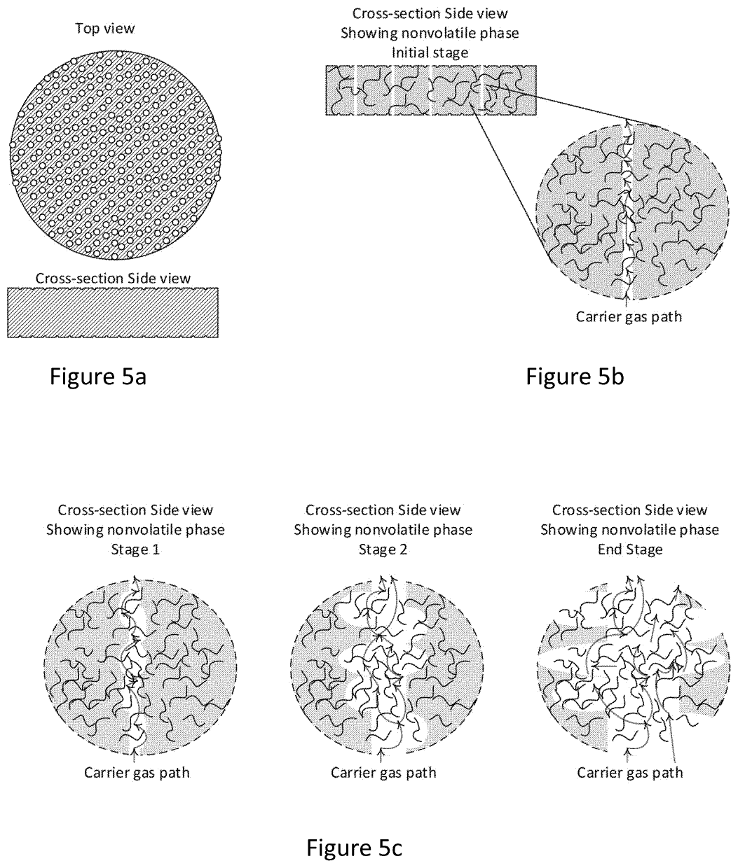

FIGS. 5A through 5C is an example of the vaporization of the solid preform. Referring to FIG. 5A, the solid material of the preform includes a combination of volatile and involatile phases. Both the top and bottom surfaces of the preform can have texture to allow lateral transport of vapor from the volatile phase as well as the carrier gas. In certain embodiments, depending on the ampule, certain through holes can also allow for vertical transport of the vapor from the volatile phase as well was the carrier gas. Referring to FIG. 5B the bottom cross section and side walls show a nonvolatile phase mixed in the volatile phase and impinging on a through hole. Through the different phases depicted in FIG. 5C, there is close contact between the carrier gas and the evaporating surfaces of the volatile phase of the preform. Accordingly, the volatile phase is evaporated while the nonvolatile phase keeps the carrier path dispersed to maintain close contact between the carrier gas and the evaporating surfaces of the volatile phase. One non-limiting exemplary advantage of the preform, is that, in the absence of the involatile phase, as the volatile phase is vaporizes, there is channeling of the carrier gas with reduced contact between the carrier gas and the volatile phase.

In an embodiment, the mold may include features that result in the preform having channels through the preform and/or grooves on one or more surfaces of the preform, such as the upper and lower flat surfaces. In an embodiment, the portions of the mold forming the channels may have a taper to facilitate operation of the mold and removal of completed preforms. In an embodiment, preparing the preform at 406 may further include forming the channels and/or grooves on the preform following the pressing of the powder or the evaporation of the solution. In an embodiment, the channels may be formed by drilling. In an embodiment, the grooves may be milled into one or more surfaces of the preform. In an embodiment, an alignment line can be provided on the preform, for example via milling, marking, a feature of the mold used to form the preform or any other suitable method for including a visible indication of alignment on an outer surface of the preform, such as a circumferential surface of the preform.

The preform may optionally be added to a solids delivery ampule 408. The preform may be placed in a stack of preforms within a body of the solids delivery ampule. The preform may be aligned such that channels through one preform are out of alignment with the channels of any adjacent preforms. This orientation of preforms within a stack may be facilitated by one or more alignment lines formed in the surface of each preform. In an embodiment, the placement into the ampule at 408 may be performed under an inter gas atmosphere.

Alternatively, the preform may be used as a vapor source independent of an ampule, when optional step 408 is omitted.

Aspects:

It is understood that any of aspects 1-11 can be combined with any of aspects 12-15 or 16-25. It is understood that any of aspects 12-15 may be combined with any of aspects 16-25.

Aspect 1. A preform for sublimation, comprising:

a support phase; and
a solid sublimation material,
wherein the solid sublimation material surrounds at least a portion of the support phase, and the preform includes a plurality of channels through the preform.

Aspect 2. The preform according to aspect 1, wherein the solid sublimation material is pressed powder.

Aspect 3. The preform according to any of aspects 1-2, wherein the support phase includes a metal foam, a lattice of solid metal, one or more metal wires, or a metal wool.

Aspect 4. The preform according to any of aspects 1-3, wherein the support phase comprises carbon fibers or ceramic fibers.

Aspect 5. The preform according to any of aspects 1-4, further comprising a foil at one of a top surface of the preform or a bottom surface of the preform.

Aspect 6. The preform according to any of aspects 1-5, further comprising a foil at a side surface of the preform.

Aspect 7. The preform according to any of aspects 1-6, wherein the solid sublimation material is aluminum chloride.

Aspect 8. The preform according to aspect 7, wherein the support phase comprises aluminum.

Aspect 9. The preform according to any of aspects 1-6, wherein the solid sublimation material comprises Mo or W.

Aspect 10. The preform according to aspect 9, wherein the support phase comprises nickel.

Aspect 11. The preform according to any of aspects 1-10, wherein the preform comprises a plurality of grooves on a surface of the preform.

Aspect 12. An ampule for delivery of a vapor, comprising:

an ampule body having a vapor outlet port, the ampule body defining an internal space containing one or more sublimation preforms, wherein each sublimation preform comprises:

a support phase; and

a solid sublimation material,

wherein the solid sublimation material surrounds at least a portion of the support phase, and the preform includes a plurality of channels through or around the preform.

Aspect 13. The ampule according to aspect 12, wherein the ampule body further comprises a carrier gas inlet.

Aspect 14. The ampule according to any of aspects 12-13, wherein each of the one or more sublimation preforms includes the same solid sublimation material.

Aspect 15. The ampule according to any of aspects 12-14, wherein the ampule body contains a plurality of the sublimation preforms, and the sublimation preforms are arranged such that the channels of each sublimation preform do not align with channels of adjacent sublimation preforms.

Aspect 16. A method of preparing solid sublimation material, comprising:

obtaining a support phase;
surrounding at least a portion of the support phase with a solid sublimation material; and
preparing a preform including the support phase and the solid sublimation material, wherein the solid sublimation material surrounds at least a portion of the support phase.

Aspect 17. The method according to aspect 16, wherein the solid sublimation material is provided in a form of a powder, and preparing the preform comprises pressing the powder and the support phase.

Aspect 18. The method according to aspect 17, wherein the pressing the powder and the support phase includes heating the powder.

Aspect 19. The method according to aspect 16, wherein the solid sublimation material is provided in a form of a solution including the solid sublimation material and a solvent, and preparing the preform comprises removing the solvent from the solution.

Aspect 20. The method according to aspect 16, wherein the solid sublimation material is provided as a vapor, and preparing the preform comprises condensing the vapor of the solid sublimation material over the support phase.

Aspect 21. The method according to aspect 16, wherein the solid sublimation material is provided in a molten form, and preparing the preform comprises cooling the molten solid sublimation material.

Aspect 22. The method according to any of aspects 16-21, further comprising placing the preform into a solids delivery ampule

Aspect 23. The method according to any of aspects 16-21, wherein preparing the preform is performed in a mold configured to form a plurality of channels through the preform and to form a plurality of grooves along at least one surface of the preform.

Aspect 24. The method according to any of aspects 16-23, further comprising drilling one or more channels in the preform and cutting a plurality of grooves along at least one surface of the preform.

Aspect 25. The method according to any of aspects 16-24, wherein preparing the preform includes contacting at least one of the solid sublimation material and the support phase with a foil.

The examples and figures disclosed in this application are to be considered in all respects as illustrative and not limitative. The scope of the invention is indicated by the appended claims rather than by the foregoing description and figures; and all changes which come within the meaning and range of equivalency of the claims are intended to be embraced therein.

1. A preform for sublimation, comprising:
a support phase; and
a solid sublimation material,
wherein the solid sublimation material surrounds at least a portion of the support phase, and
the preform includes a plurality of channels through the preform.

2. The preform of claim 1, wherein the solid sublimation material is pressed powder.

3. The preform of claim 1, wherein the support phase includes a metal foam, a lattice of solid metal, one or more metal wires, or a metal wool.

4. The preform of claim 1, wherein the support phase comprises carbon fibers or ceramic fibers.

5. The preform of claim 1, further comprising a foil at one of a top surface of the preform or a bottom surface of the preform.

6. The preform of claim 1, further comprising a foil at a side surface of the preform.

7. The preform of claim 1, wherein the solid sublimation material is aluminum chloride.

8. The preform of claim 1, wherein the solid sublimation material comprises Mo or W.

9. The preform of claim 1, wherein the preform comprises a plurality of grooves on a surface of the preform.

10. An ampule for delivery of a vapor, comprising:
an ampule body having a vapor outlet port, the ampule body defining an internal space containing one or more sublimation preforms, wherein each sublimation preform comprises:
a support phase; and
a solid sublimation material,
wherein the solid sublimation material surrounds at least a portion of the support phase, and
the preform includes a plurality of channels through or around the preform.

11. The ampule of claim 10, wherein the ampule body further comprises a carrier gas inlet.

12. The ampule of claim 10, wherein each of the one or more sublimation preforms includes the same solid sublimation material.

13. The ampule of claim 10, wherein the ampule body contains a plurality of the sublimation preforms, and the sublimation preforms are arranged such that the channels of each sublimation preform do not align with channels of adjacent sublimation preforms.

14. A method of preparing solid sublimation material, comprising:
obtaining a support phase;
surrounding at least a portion of the support phase with a solid sublimation material; and
preparing a preform including the support phase and the solid sublimation material,
wherein the solid sublimation material surrounds at least a portion of the support phase.

15. The method of claim 14, wherein the solid sublimation material is provided in a form of a powder, and preparing the preform comprises pressing the powder and the support phase.

16. The method of claim 14, wherein the pressing the powder and the support phase includes heating the powder.

17. The method of claim 14, wherein the solid sublimation material is provided in a form of a solution including the solid sublimation material and a solvent, and preparing the preform comprises removing the solvent from the solution.

18. The method of claim 14, wherein the solid sublimation material is provided as a vapor, and preparing the preform comprises condensing the vapor of the solid sublimation material over the support phase.

19. The method of claim 14, wherein the solid sublimation material is provided in a molten form, and preparing the preform comprises cooling the molten solid sublimation material.
